(19) United States
(12) Patent Application Publication
(10) Pub. No.: US 2026/0130173 A1
(43) Pub. Date: May 7, 2026

(54) APPARATUS FOR FABRICATING DISPLAY DEVICE

(71) Applicant: Samsung Display Co., LTD., Yongin-si (KR)

(72) Inventors: Min Ho BAE, Yongin-si (KR); Sung Jin KIM, Yongin-si (KR); Jun Ha PARK, Yongin-si (KR); Jae Won SHIM, Yongin-si (KR); Suk Won JUNG, Yongin-si (KR); Jeong Won HAN, Yongin-si (KR)

(21) Appl. No.: 19/375,317

(22) Filed: Oct. 31, 2025

(30) Foreign Application Priority Data
Nov. 1, 2024 (KR) 10-2024-0153729

(51) Int. Cl. H01L 21/683; C23C 14/04; H10K 71/16

(52) U.S. Cl. CPC H10P 72/722; C23C 14/042; H10K 71/166

(57) ABSTRACT

An apparatus for fabricating a display device includes: a mask electrostatic-chuck; a mask support placed on the mask electrostatic-chuck; and a mask placed on the mask support. The mask electrostatic-chuck may include: a seating portion onto which the mask support is seated; a contact portion configured to contact the mask; and a position alignment portion configured to align a position of the mask support.

The application claims priority to Korean patent application number 10-2024-0153729, filed on Nov. 1, 2024, and all the benefits accruing therefrom under 35 U.S.C. § 119, the content of which in its entirety is herein incorporated by reference.

### BACKGROUND

### 1. Field

Various embodiments of the disclosure relate to an apparatus for fabricating a display device, a method of fabricating the display device, and an electronic device.

### 2. Description of Related Art

With the development of information technology, the importance of display devices as a medium which connects users and information has become increasingly emphasized. Accordingly, research and development on display devices have been continuously conducted.

Display devices may be formed by placing a patterned mask on a substrate and depositing materials onto the substrate. For the materials to be properly formed on the substrate, it is important to ensure that the mask is securely and appropriately fixed in place.

### SUMMARY

A feature of the disclosure is directed to an apparatus for fabricating a display device, in which a mask may be appropriately secured to minimize a gap between the mask and a substrate and improve parallelism between the mask and the substrate, and to a method of fabricating the display device, and an electronic device.

A feature of the disclosure is directed to an apparatus for fabricating a display device, capable of automatically replacing a mask support which supports the mask with another, and to a method of fabricating the display device, and an electronic device.

The features of the disclosure are not limited to the above-stated objects, and those skilled in the art will clearly understand other not mentioned objects from the accompanying claims.

An embodiment of the disclosure may provide an apparatus for fabricating a display device, including: a mask electrostatic-chuck; a mask support placed on the mask electrostatic-chuck; and a mask placed on the mask support. The mask electrostatic-chuck may include: a seating portion onto which the mask support is seated; a contact portion configured to contact the mask; and a position alignment portion configured to align a position of the mask support.

In an embodiment, the mask electrostatic-chuck may further include a peripheral portion disposed outside the contact portion. A height of the peripheral portion may be lower than a height of the contact portion.

In an embodiment, a height of the seating portion may be lower than the height of the contact portion.

In an embodiment, the seating portion and the contact portion may have different heights from each other. A difference between the heights of the seating portion and the contact portion may be equal to or greater than a thickness of the mask support.

In an embodiment, the apparatus may further include a transfer component configured to transfer at least one of the mask support or the mask. The transfer portion may not contact the peripheral portion.

In an embodiment, the apparatus may further include: a camera. A camera may pass through the contact portion. The camera may correspond to the camera hole. The camera may capture an image of the mask.

In an embodiment, the position alignment portion may include a groove defined in the peripheral portion.

In an embodiment, in a cross-sectional view, the groove may have a constant width, or a width decreasing from one end thereof to an opposite end.

In an embodiment, the mask support may include: a support frame; and a guide which is connected to the support frame and protrudes from the support frame. The guide may be placed on the position alignment portion.

In an embodiment, the guide may have a rod shape in a plan view.

In an embodiment, the mask support may further include an outer guide frame connected to the guide. The outer guide frame may have a ring shape in a plan view.

In an embodiment, the position alignment portion may include: a protrusion which is connected to the seating portion and protrudes from the seating portion; and a pin. A protrusion hole may pass through at least a portion of the protrusion. The pin may be inserted into the protrusion hole. The pin may protrude further than an upper surface of the protrusion.

In an embodiment, the contact portion may be connected to the seating portion. The peripheral portion may be connected to the contact portion.

In an embodiment, in a cross-sectional view, the pin may have a constant width, or a width decreasing from one end thereof to an opposite end.

In an embodiment, the mask support may define, therein, a guide hole which passes through the mask support. The pin may be inserted into the guide hole.

In an embodiment, the guide hole may include a first guide hole and a second guide hole. The second guide hole may have a larger area than an area of the first guide hole, in a plan view.

An embodiment of the disclosure may provide an apparatus for fabricating a display device, including: a substrate; a substrate electrostatic-chuck placed on the substrate; a mask configured to correspond to a pattern of a material formed on the substrate; a mask electrostatic-chuck disposed under the mask; and a substrate electrostatic-chuck moving component configured to move the substrate electrostatic-chuck. The substrate electrostatic-chuck moving component may move the substrate electrostatic-chuck and change a shape of the substrate.

In an embodiment, the apparatus may further include: a pressure sensor configured to measure a pressure applied to the substrate; and a distance sensor configured to measure a distance between the substrate and the mask. The substrate may be bendable by the substrate electrostatic-chuck moving component.

An embodiment of the disclosure may provide an apparatus for fabricating a display device, including: a substrate; a substrate electrostatic-chuck placed on the substrate; a mask configured to correspond to a pattern of a material formed on the substrate; a mask electrostatic-chuck disposed under the mask; and a mask electrostatic-chuck moving component configured to move the mask electrostatic-chuck. The mask electrostatic-chuck moving component may move the mask electrostatic-chuck and change a shape of the mask.

In an embodiment, the mask electrostatic-chuck may include a plurality of mask electrostatic-chucks. The mask electrostatic-chucks may be movable to be spaced apart from each other. The mask electrostatic-chuck moving component may include the number of mask electrostatic-chuck moving components corresponding to the number of mask electrostatic-chucks. The mask electrostatic-chuck moving component may tension the mask.

An embodiment of the disclosure may provide a method of fabricating a display device, including: forming a pixel circuit layer on a substrate; and forming a light-emitting element on the pixel circuit layer. Forming the light-emitting element may include depositing an emission layer using an apparatus for fabricating the display device. The apparatus may include: a mask electrostatic-chuck; a mask support placed on the mask electrostatic-chuck; and a mask which allows a material for depositing the emission layer on the mask support to pass through the mask. The mask electrostatic-chuck may include: a seating portion onto which the mask support is seated; a contact portion configured to contact the mask; and a position alignment portion configured to align a position of the mask support.

An embodiment of the disclosure may provide a method of fabricating a display device, including: forming a pixel circuit layer on a substrate; and forming a light-emitting element on the pixel circuit layer. Forming the light-emitting element may include depositing an emission layer using an apparatus for fabricating the display device. The apparatus may include: a substrate electrostatic-chuck configured to secure the substrate; a mask corresponding to a pattern of the emission layer; a mask electrostatic-chuck disposed under the mask; and a substrate electrostatic-chuck moving component configured to move the substrate electrostatic-chuck. The substrate electrostatic-chuck moving component may move the substrate electrostatic-chuck and change a shape of the substrate.

An embodiment of the disclosure may provide a method of fabricating a display device, including: forming a pixel circuit layer on a substrate; and forming a light-emitting element on the pixel circuit layer. Forming the light-emitting element may include depositing an emission layer using an apparatus for fabricating the display device. The apparatus may include: a substrate electrostatic-chuck configured to secure the substrate; a mask corresponding to a pattern of the emission layer; a mask electrostatic-chuck disposed under the mask; and a mask electrostatic-chuck moving component configured to move the mask electrostatic-chuck. The mask electrostatic-chuck moving component may move the mask electrostatic-chuck and changes a shape of the mask.

An embodiment of the disclosure may provide an electronic device including: a processor; and a display device including pixels, and configured to display images on the pixels under control of the processor. The display device may be fabricated by the fabrication method.

### BRIEF DESCRIPTION OF THE DRAWINGS

The above and other embodiments, advantages and features of this disclosure will become more apparent by describing in further detail embodiments thereof with reference to the accompanying drawings.

FIG. 1 is a schematic cross-sectional view illustrating an embodiment of an apparatus for fabricating a display device.

FIG. 2 is a schematic plan view illustrating an embodiment of a mask.

FIGS. 3 and 4 are schematic plan views each illustrating an embodiment of a mask support.

FIG. 5 is a schematic enlarged view illustrating an embodiment of a mask electrostatic-chuck.

FIG. 6 is a schematic enlarged view illustrating an embodiment of a guide placed on a position alignment portion.

FIG. 7 is a schematic cross-sectional view illustrating an embodiment of the fabrication apparatus.

FIG. 8 is a schematic perspective view illustrating an embodiment of the mask support placed on the mask electrostatic-chuck.

FIG. 9 is a schematic plan view illustrating an embodiment of a mask support.

FIG. 10 is a schematic enlarged view illustrating an embodiment of a mask electrostatic-chuck.

FIG. 11 is a schematic cross-sectional view illustrating an embodiment of an apparatus for fabricating a display device.

FIG. 12 is a schematic perspective view illustrating an embodiment of the mask support placed on the mask electrostatic-chuck.

FIG. 13 is a schematic cross-sectional view illustrating an embodiment of an apparatus for fabricating a display device.

FIG. 14 is a schematic cross-sectional view illustrating an embodiment of the fabrication apparatus.

FIG. 15 is a schematic plan view illustrating an embodiment of the mask electrostatic-chuck.

FIG. 16 is a plan view illustrating an embodiment of the display device in embodiments.

FIG. 17 is a plan view illustrating an embodiment of a sub-pixel.

FIG. 18 is a cross-sectional view taken along line I-I′ of FIG. 17.

FIG. 19 is a flowchart illustrating an embodiment of a method of fabricating the display device.

FIG. 20 is a block diagram illustrating an embodiment of an electronic device including the display device of FIG. 18.

FIG. 21 is a perspective view illustrating an embodiment of a smartphone which may be implemented using the electronic device of FIG. 20.

FIG. 22 is a perspective view illustrating an embodiment of a tablet computer which may be implemented using the electronic device of FIG. 20.

### DETAILED DESCRIPTION

Hereinafter, embodiments of the disclosure will be described in detail with reference to the attached drawings. In the following description, only parts required for understanding of operations in accordance with the disclosure will be described, and explanation of the other parts will be omitted not to make the gist of the disclosure unclear. Accordingly, the disclosure is not limited to the embodiments set forth herein but may be embodied in other types. Rather, these embodiments are provided so that the disclosure will be thorough and complete, and will fully convey the technical spirit of the disclosure to those skilled in the art.

It will be understood that in case that an element is referred to as being “coupled” or “connected” to another element, it may be directly coupled or connected, or intervening elements may be therebetween. The terminology used herein is for the purpose of describing particular embodiments only and is not intended to be limiting. In the specification, in case that an element is referred to as “comprising” or “including” a component, it does not preclude another component, but may further include other components unless the context clearly indicates otherwise. “at least one of X, Y, or Z” and “at least one selected from the group consisting of X, Y, and Z” may be construed as X only, Y only, Z only, or any combination of two or more of X, Y, or Z (for instance, XYZ, XYY, YZ, or ZZ). As used herein, the term “and/or” may include any and all combinations of one or more of the associated listed items.

Although the terms “first,” “second,” or the like may be used herein to describe various types of elements, these elements should not be limited by these terms. These terms are only used to distinguish one element from other elements. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” may encompass both an orientation of above and below. Furthermore, the device may be otherwise oriented (e.g., rotated 90 degrees or at other orientations), and, as such, the spatially relative descriptors used herein interpreted accordingly.

Various embodiments will be described with reference to diagrams illustrating idealized embodiments. As such, variations from the shapes of the illustrations as a result, for example, of manufacturing techniques and/or tolerances, are to be expected. Therefore, embodiments disclosed herein should not be construed as limited to the particular illustrated shapes, but are to include deviations in shapes that result from, for instance, manufacturing. As such, the shapes illustrated in the drawings may not illustrate the actual shapes of regions of a device, and, as such, are not intended to be limiting.

Various embodiments of the disclosure relate to an apparatus for fabricating a display device, a method of fabricating the display device, and an electronic device. The apparatus for fabricating the display device may include at least one of a mask fixing device or a deposition device. Hereinafter, a description will be provided based on an embodiment in which the apparatus for fabricating the display device includes a deposition device. However, the disclosure is not limited to the aforementioned embodiment. Hereinafter, embodiments of the disclosure will be described in detail with reference to the accompanying drawings.

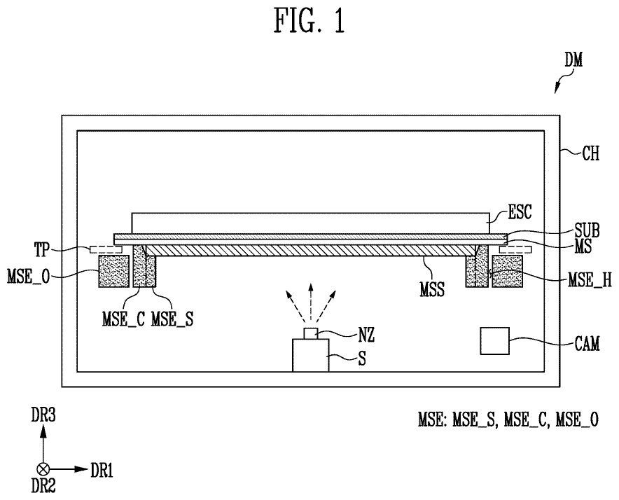

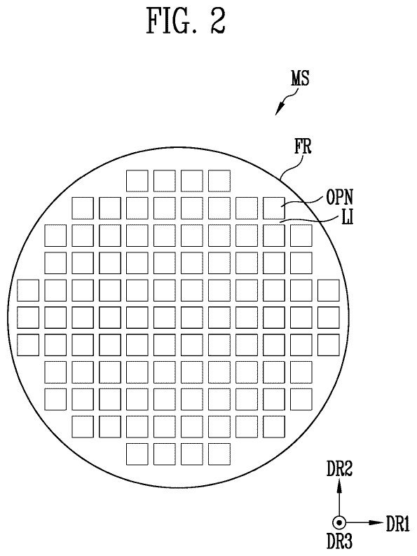

FIG. 1 is a schematic cross-sectional view illustrating an embodiment of an apparatus DM for fabricating a display device. FIG. 2 is a schematic plan view illustrating an embodiment of a mask MS.

Referring to FIG. 1, the display device fabrication apparatus DM (referred also to as “fabrication apparatus DM”) may deposit deposition material onto a substrate SUB. The fabrication apparatus DM may include a chamber CH, a substrate electrostatic-chuck ESC, a mask support MSS, a mask electrostatic-chuck MSE, a camera CAM, and/or a deposition source S.

The chamber CH may define an internal space, allowing a deposition process to be performed in the internal space of the chamber CH. In an embodiment, the substrate electrostatic-chuck ESC, the mask support MSS, the mask electrostatic-chuck MSE, the camera CAM, and/or the deposition source S may be provided in the chamber CH, for example.

In an embodiment, the chamber CH may define an opening therein. In an embodiment, a gate valve or the like may be disposed in the opening of the chamber CH. The opening of the chamber CH may be opened or closed by the gate valve or the like.

The mask support MSS may support or secure the mask MS. In an embodiment, the mask support MSS may be disposed under the mask MS, thus preventing the mask MS from sagging due to gravity, for example.

The mask electrostatic-chuck MSE may be disposed under the mask support MSS to move the mask support MSS within a predetermined distance range in an up-down direction and/or a left-right direction, or rotate the mask support MSS within a predetermined angular range. The mask electrostatic-chuck MSE may use electrostatic force to secure the mask MS.

The mask electrostatic-chuck MSE may include a seating portion MSE_S, a contact portion MSE_C, and a peripheral portion MSE_O. The seating portion MSE_S may be an area where the mask support MSS is seated. The mask support MSS may be placed on the seating portion MSE_S of the mask electrostatic-chuck MSE. The mask support MSS may contact at least a portion of the seating portion MSE_S.

The contact portion MSE_C may include an area where the mask MS contacts the mask electrostatic-chuck MSE. The mask MS may be chucked and secured to the contact portion MSE_C by electrostatic force. The contact portion MSE_C may define a camera hole MSE_H which passes through at least an area of the contact portion MSE_C.

The peripheral portion MSE_O may be disposed outside the seating portion MSE_S and the contact portion MSE_C (e.g., farther from a center of the mask MS in a plan view), and may enclose the seating portion MSE_S and the contact portion MSE_C in a plan view.

The mask MS may be placed on the mask support MSS and the mask electrostatic-chuck MSE. The mask MS may include a fine metal mask (“FMM”) or a silicon mask.

Referring to FIG. 2, the mask MS may define an opening OPN therein, and include a frame FR provided with ribs LI which define the opening OPN. The ribs LI may be coupled (or connected) to the frame FR, with some of the ribs LI extending in a first direction DR1 and remaining (the other) ribs LI extending in a second direction DR2, thereby defining the opening OPN. Hereinafter, the first direction DR1 and the second direction DR2 may refer to directions in which a plane where the substrate SUB is placed extends, while a third direction DR3 may refer to a direction perpendicular to the plane where the substrate SUB is placed.

In an embodiment, the opening OPN may be provided in plural. In an embodiment, a plurality of openings OPN may be defined in the frame FR of the mask MS, for example. The openings OPN may form a pattern. In an embodiment, the pattern of the mask MS may correspond to a deposition pattern formed in the substrate SUB, for example.

In FIG. 2, the frame FR is illustrated as having a circular shape, but the disclosure is not limited thereto. The frame FR may have various shapes.

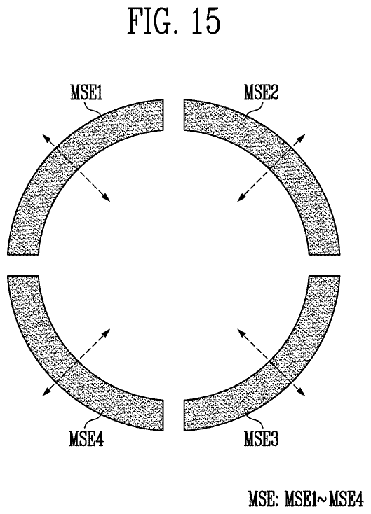

Referring back to FIG. 1, the substrate SUB which allows deposition material to be deposited thereon is placed on the mask electrostatic-chuck MSE and/or the mask MS. The substrate SUB may be a mother board (or substrate) of a display device DD (refer to FIG. 16).

The substrate electrostatic-chuck ESC may be placed on the substrate SUB. The substrate electrostatic-chuck ESC may be disposed on the mask electrostatic-chuck MSE and/or the mask MS. The substrate electrostatic-chuck ESC may function to secure the substrate SUB using electrostatic force and to closely attach the substrate SUB to the mask MS. The substrate electrostatic-chuck ESC may be coupled to the substrate SUB, thereby preventing the substrate SUB from moving during a deposition process. The substrate electrostatic-chuck ESC may include electrodes arranged therein. The electrodes may include at least one first electrode and at least one second electrode. The at least one first electrode may have a first polarity, while the at least one second electrode may have second polarity opposite to the first polarity. In an embodiment, the fabrication apparatus DM may further include a driver which drives the substrate electrostatic-chuck ESC. The driver may be connected to the substrate electrostatic-chuck ESC to drive the substrate electrostatic-chuck ESC. In an embodiment, the driver may include a power supply, for example. The power supply of the driver may be electrically connected to the electrodes of the substrate electrostatic-chuck ESC (e.g., the first electrode and the second electrode). As the power supply of the driver applies a predetermined voltage to the substrate electrostatic-chuck ESC, electrostatic force may be generated in the substrate electrostatic-chuck ESC. Accordingly, the substrate SUB and the mask MS may be brought into close contact with each other by the electrostatic force. In an embodiment, because the electrostatic force generated from the substrate electrostatic-chuck ESC may pull the substrate SUB and the mask MS in a direction (e.g., the third direction DR3) toward the substrate electrostatic-chuck ESC (e.g., because attractive force is generated between the substrate electrostatic-chuck ESC and the substrate SUB and/or the substrate electrostatic-chuck ESC and the mask MS), the coupling force between the substrate SUB and the mask MS may increase, and the substrate SUB and the mask MS may be prevented from sagging, for example.

In an embodiment, in the case where the mask MS is a fine metal mask, a yoke plate with a permanent magnet may further be placed on the substrate electrostatic-chuck ESC. As the yoke plate is placed to overlap the substrate electrostatic-chuck ESC, the substrate SUB and the mask MS may be more closely attached to each other by not only electrostatic force generated from the substrate electrostatic-chuck ESC but also magnetic force generated from the yoke plate. In an embodiment, the magnetic force generated by the yoke plate may pull the mask (e.g., fine metal mask) including or consisting of metal in a direction toward the yoke plate (e.g., in the third direction DR3), thereby further increasing the coupling force between the substrate SUB and the mask MS and preventing the mask MS from sagging, for example.

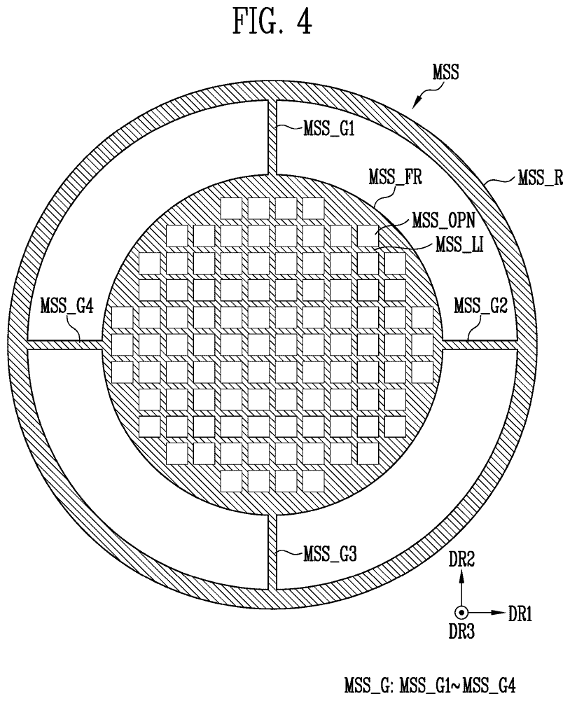

In an embodiment, the fabrication apparatus DM may further include a transfer component TP which transfers at least one of the mask MS or the mask support MSS. The transfer component TP may move at least one of the mask MS or the mask support MSS within a predetermined distance range in the up-down direction and/or the left-right direction, thereby enabling replacement of at least one of the mask MS or the mask support MSS with another. In the fabrication apparatus DM in an embodiment, the peripheral portion MSE_O is formed lower than the contact portion MSE_C, thereby preventing contact with the mask electrostatic-chuck MSE during the entry of the transfer component TP. A description related to the aforementioned structure will be provided below with reference to FIG. 5.

The camera CAM may be placed below (or to correspond to) the camera hole MSE_H. In an embodiment, the camera CAM may be disposed under the mask electrostatic-chuck MSE that defines the camera hole MSE_H therein, for example. The camera CAM may capture images of the mask MS and the substrate SUB. In an embodiment, the camera CAM may capture alignment marks formed in the mask MS and the substrate SUB to measure alignment accuracy between the substrate SUB and the mask MS, for example.

The deposition source S may be disposed in the chamber CH. The deposition material may be provided in the deposition source S. The deposition source S may evaporate at least one deposition material of organic material, inorganic material, or conductive material toward the mask MS. The deposition material may be deposited onto the substrate SUB through the mask MS. In an embodiment, the deposition source S may deposit the deposition material onto the substrate SUB by heating the deposition material to a relatively high temperature to evaporate the deposition material, for example. In an embodiment, the deposition source S may include a heater to heat the deposition material, for example.

A nozzle component NZ may be connected to the deposition source S to provide the deposition material that is vaporized or sublimated from the deposition source S to the outside. The nozzle component NZ may include at least one nozzle. In an embodiment, the nozzle may include dot nozzles which are spaced apart from each other and arranged in a dot pattern, for example. In another embodiment, the nozzle may include a line nozzle which sprays deposition material over a predetermined area. In an embodiment, the fabrication apparatus DM may further include a pressure controller. The pressure controller may be connected to the chamber CH to adjust the pressure in the chamber CH. In an embodiment, the pressure controller may include a connection pipe connected to the chamber CH, and a pump provided on the connection pipe, for example. The connection pipe may be connected to a separate device which performs removal of external contaminants.

Process yield may be affected by evenness of the mask MS and manual replacement of the mask MS during the deposition process. In an embodiment, in the case where a gap occurs between the mask MS and the substrate SUB (or in the case the mask MS is sagging due to gravity), the deposition material may not be normally deposited on the substrate SUB, leading to an increase in process variation and a reduction in yield, thereby decreasing the reliability of the deposition process, for example. Furthermore, in the case where the mask MS is manually replaced with another for reasons, such as cleaning the mask MS, the yield may decrease due to time desired for the replacement.

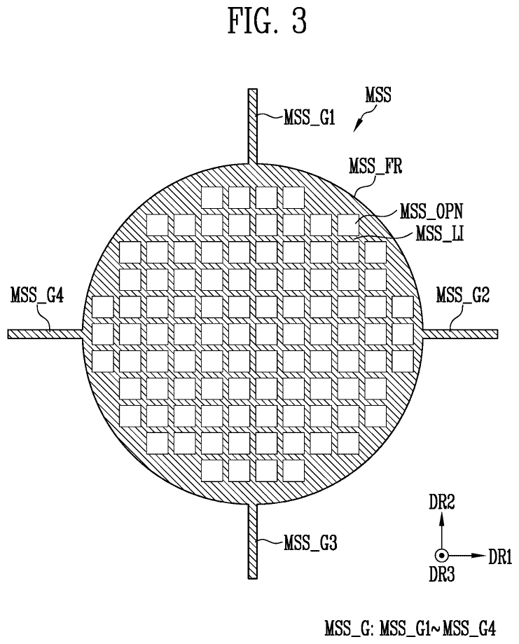

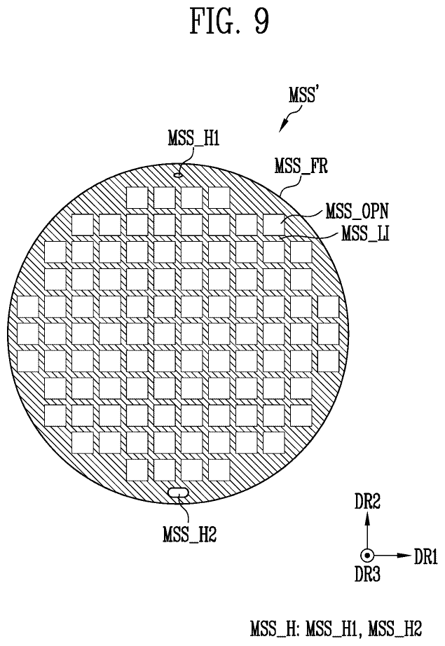

Therefore, it is desirable to adjust the evenness of the mask MS and automatically replace the mask MS with another. To achieve the aforementioned purpose, the fabrication apparatus DM in an embodiment may include the mask support MSS and the mask electrostatic-chuck MSE, and the mask electrostatic-chuck MSE may further include a position alignment portion MSE_A (refer to FIGS. 5 and 10). For a detailed description pertaining to the foregoing, FIGS. 3 to 12 may be referenced.

FIGS. 3 to 8 illustrate an embodiment of the fabrication apparatus DM.

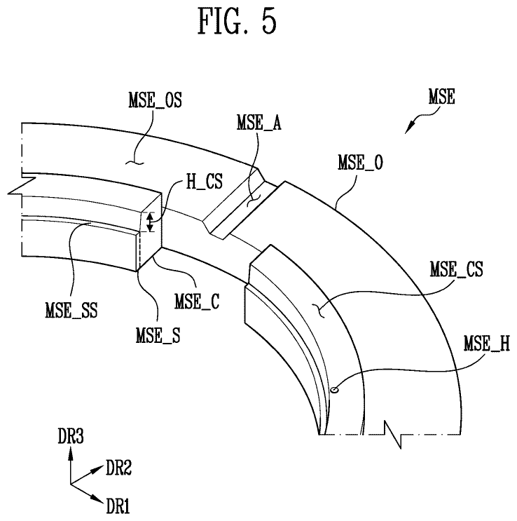

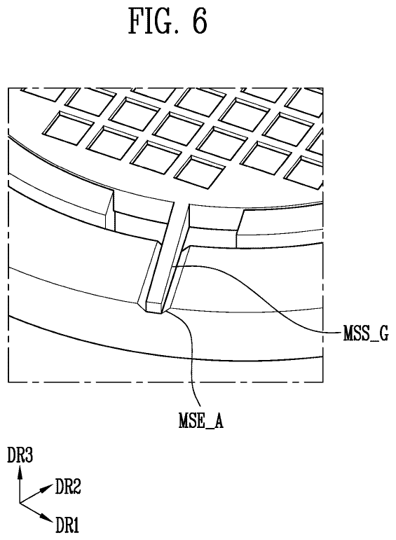

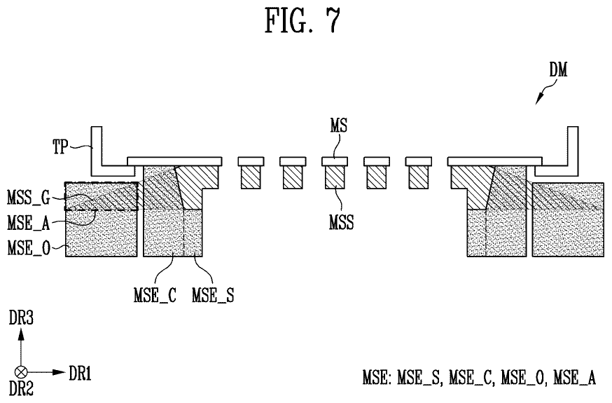

FIGS. 3 and 4 are schematic plan views each illustrating the mask support MSS. FIG. 5 is a schematic enlarged view illustrating the mask electrostatic-chuck MSE. FIG. 6 is a schematic enlarged view illustrating a guide MSS_G placed on the position alignment portion MSE_A. FIG. 7 is a schematic cross-sectional view illustrating the fabrication apparatus DM. FIG. 8 is a schematic perspective view illustrating the mask support MSS placed on the mask electrostatic-chuck MSE.

Referring to FIG. 3, the mask support MSS may define a support opening MSS_OPN therein, and may include a support frame MSS_FR provided with support ribs MSS_LI which define the support opening MSS_OPN. The support ribs MSS_LI may be coupled (or connected) to the support frame MSS_FR, with some of the support ribs MSS_LI extending in the first direction DR1 and remaining (the other) support ribs MSS_LI extending in the second direction DR2, thereby defining the support opening MSS_OPN.

In an embodiment, the support opening MSS_OPN may include a plurality of support openings MSS_OPN. In an embodiment, a plurality of support openings MSS_OPN may be defined in the support frame MSS_FR of the mask support MSS, for example. The number of support openings MSS_OPN may correspond to the number of openings OPN of the mask MS. The support openings MSS_OPN may form a pattern. In an embodiment, the pattern of the mask support MSS may correspond to a deposition pattern formed in the substrate SUB, for example.

A distance between the support openings MSS_OPN may be less than or equal to that between the mask openings OPN. A width of each of the support openings MSS_OPN may be equal to or greater than that of each of the mask openings OPN. Accordingly, the mask support MSS may support the mask MS without covering the pattern of the mask MS.

The mask support MSS in an embodiment may include the guide MSS_G. The guide MSS_G may protrude from the support frame MSS_FR, and may be connected to the support frame MSS_FR. In an embodiment, protruding from the support frame MSS_FR, the guide MSS_G may be unitary with the support frame MSS_FR, for example.

The guide MSS_G may have a rod shape in a plan view. In an embodiment, in a plan view, the guide MSS_G may have a quadrangular shape, e.g., rectangular shape or a trapezoidal shape with a width reducing from one end to an opposite end, for example.

In an embodiment, the guide MSS_G may be provided as a plurality of units. In an embodiment, the guide MSS_G may include a first guide MSS_G1, a second guide MSS_G2, a third guide MSS_G3, and a fourth guide MSS_G4, for example.

Although FIG. 3 illustrates an embodiment in which four guides MSS_G are provided, the disclosure is not limited thereto. In an embodiment, the guide MSS_G may be provided as a single unit or as two or more units, for example. In an embodiment, in the case where the guide MSS_G is provided as two or more units, the mask support MSS may be more stably seated on the mask electrostatic-chuck MSE.

The first guide MSS_G1, the second guide MSS_G2, the third guide MSS_G3, and the fourth guide MSS_G4 may be arranged in a clockwise direction. In an embodiment, in a plan view, the first guide MSS_G1 may be disposed on an upper side of the support frame MSS_FR, the second guide MSS_G2 may be disposed on a right side of the support frame MSS_FR, the third guide MSS_G3 may be disposed on a lower side of the support frame MSS_FR, and the fourth guide MSS_G4 may be disposed on a left side of the support frame MSS_FR, for example.

In FIG. 3, an example is illustrated where the first guide MSS_G1 is arranged to form an angle of 90° with each of the second guide MSS_G2 and the fourth guide MSS_G4, and the third guide MSS_G3 is arranged to form an angle of 90° with each of the second guide MSS_G2 and the fourth guide MSS_G4. However, the disclosure is not limited to the aforementioned embodiment. In an embodiment, an angle of each of the first guide MSS_G1 and the third guide MSS_G3 with respect to the second guide MSS_G2 may be either acute or obtuse, for example. An angle of each of the first guide MSS_G1 and the third guide MSS_G3 with respect to the fourth guide MSS_G4 may be either acute or obtuse.

The mask support MSS in an embodiment of the disclosure may include metal. However, the disclosure is not limited to the aforementioned embodiment.

Referring to FIG. 4, the mask support MSS in an embodiment may further include an outer guide frame MSS_R. The outer guide frame MSS_R may be connected to the guide MSS_G. In an embodiment, the outer guide frame MSS_R may be unitary with the guide MSS_G, for example. The outer guide frame MSS_R, the guide MSS_G, the support frame MSS_FR, and the support rib MSS_LI may each include metal, and may be integrated with each other.

The outer guide frame MSS_R may have a ring shape in a plan view. In an embodiment, the outer guide frame MSS_R may have a doughnut shape in a plan view, for example. The outer guide frame MSS_R may enclose the support frame MSS_FR in a plan view.

Referring to FIG. 5, the mask electrostatic-chuck MSE may include the seating portion MSE_S, the contact portion MSE_C, and the peripheral portion MSE_O. In a plan view, the seating portion MSE_S may be disposed further inward than the contact portion MSE_C, and the contact portion MSE_C may be disposed further inward than the peripheral portion MSE_O. In the description, “being disposed further inward than” may refer to “being disposed closer to a center of the mask MS in a plan view”. The seating portion MSE_S may be connected to the contact portion MSE_C. The contact portion MSE_C may be connected to the peripheral portion MSE_O.

The seating portion MSE_S and the contact portion MSE_C may have different heights from each other. The seating portion MSE_S and the contact portion MSE_C may form a step H_CS. The step H_CS may correspond to a difference in height between the seating portion MSE_S and the contact portion MSE_C.

An upper surface MSE_SS of the seating portion MSE_S and an upper surface of the contact portion MSE_C may be disposed at different positions. In an embodiment, the height of the seating portion MSE_S may be less than that of the contact portion MSE_C, for example. Hereinafter, the height may be defined as a vertical distance from a lower surface to an upper surface in the third direction DR3.

In an embodiment, a height of the step H_CS formed between the seating portion MSE_S and the contact portion MSE_C may be constant. In an embodiment, the contact portion MSE_C may have a constant thickness from one end connected to the seating portion MSE_S to an opposite end connected to the peripheral portion MSE_O, for example. An angle defined between the upper surface MSE_SS of the seating portion MSE_S and a side surface of the contact portion MSE_C may be approximately 90°. A distance between the upper surface MSE_SS of the seating portion MSE_S and the upper surface of the contact portion MSE_C may be constant. However, the disclosure is not limited to the aforementioned embodiment.

In an embodiment, the height of the step H_CS formed between the seating portion MSE_S and the contact portion MSE_C may increase as the distance from the seating portion MSE_S increases and then become constant, for example. In an embodiment, the contact portion MSE_C may include a first portion with a thickness increasing from one end connected to the seating portion MSE_S to an opposite end connected to the peripheral portion MSE_O, and a second portion which is connected to the first portion and has a constant thickness, for example. The angle defined between the upper surface MSE_SS of the seating portion MSE_S and the side surface of the contact portion MSE_C may be greater than 90° and less than 180°. In this case, the contact portion MSE_C may include a tapered (or inclined) side surface.

The step H_CS may be equal to or greater than a thickness of the mask support MSS. The thickness of the mask support MSS may be defined as a thickness of the support frame MSS_FR in the third direction DR3. The step H_CS may be equal to or greater than the thickness of the mask support MSS, so that the mask support MSS does not protrude from the upper surface of the contact portion MSE_C in the third direction DR3 when the mask support MSS is seated on the seating portion MSE_S.

Because the step H_CS is formed in the mask electrostatic-chuck MSE, the mask support MSS may be stably placed on the upper surface MSE_SS of the seating portion MSE_S, and the mask support MSS may reliably secure the mask MS, thereby minimizing the gap between the mask MS and the substrate SUB, and enhancing parallelism between the mask MS and the substrate SUB.

The contact portion MSE_C may include a contact surface MSE_CS which contacts the mask MS. The contact surface MSE_CS may be defined as a chucking surface which chucks the mask MS when the contact portion MSE_C contacts the mask MS, and may correspond to the upper surface of the contact portion MSE_C.

The contact portion MSE_C may define the camera hole MSE_H which passes through the contact portion MSE_C. The camera hole MSE_H may pass through a portion of the contact portion MSE_C in the third direction DR3. The camera hole MSE_H may be disposed around an edge of the contact surface MSE_CS in a plan view.

The peripheral portion MSE_O may be connected to the contact portion MSE_C, and may be disposed outside the contact portion MSE_C. The peripheral portion MSE_O may have a ring shape (or a doughnut shape) in a plan view.

The contact portion MSE_C and the peripheral portion MSE_O may have different heights from each other. In an embodiment, an upper surface MSE_OS of the peripheral portion MSE_O and the upper surface (e.g., the contact surface MSE_CS) of the contact portion MSE_C may be disposed at different positions, for example. In an embodiment, the height of the peripheral portion MSE_O may be less than that of the contact portion MSE_C, for example. In an embodiment, the upper surface MSE_OS of the peripheral portion MSE_O may be disposed at a position lower than the upper surface (e.g., the contact surface MSE_CS) of the contact portion MSE_C, for example. Accordingly, when the transfer component TP enters next (adjacent) to the mask MS to transfer at least one of the mask MS or the mask support MSS, the transfer component TP may not contact the mask electrostatic-chuck MSE (e.g., the peripheral portion MSE_O), thereby avoiding interference between the transfer component TP and the mask electrostatic-chuck MSE.

The peripheral portion MSE_O may further include the position alignment portion MSE_A. The position alignment portion MSE_A may correspond to a groove defined in the peripheral portion MSE_O. In an embodiment, the position alignment portion MSE_A may correspond to a groove defined by recessing a portion of the upper surface MSE_OS of the peripheral portion MSE_O in a direction opposite to the third direction DR3, for example. The position alignment portion MSE_A may extend in a direction crossing the peripheral portion MSE_O (e.g., the second direction DR2), and may correspond to the groove defined in the upper surface MSE_OS of the peripheral portion MSE_O.

In a cross-sectional view, the position alignment portion MSE_A may have a quadrangular shape, e.g., rectangular shape with a constant width, or may have a trapezoidal shape with a width increasing from one end to an opposite end. In an embodiment, in a cross-sectional view, the position alignment portion MSE_A may have a shape with a constant width in the third direction DR3 or may have a trapezoidal shape (or a tapered shape) which increases in width in the third direction DR3, for example.

Referring to FIG. 6, the guide MSS_G may be placed on the position alignment portion MSE_A. The guide MSS_G may be seated into the groove of the mask electrostatic-chuck MSE. To achieve the aforementioned purpose, the width of the position alignment portion MSE_A may be equal to that of the guide MSS_G. In an embodiment, the width of the position alignment portion MSE_A may be greater than that of the guide MSS_G within a range in which the mask support MSS is not excessively rotated (or moved) while the guide MSS_G is placed on the position alignment portion MSE_A.

In an embodiment, in the case where the groove of the position alignment portion MSE_A has a trapezoidal shape (or a tapered shape) with a width increasing in the third direction DR3 in a cross-sectional view, the guide MSS_G may be more easily placed on the position alignment portion MSE_A.

The guide MSS_G may guide the mask support MSS so that the mask support MSS may be disposed at a correct position on the mask electrostatic-chuck MSE. In an embodiment, referring to FIGS. 7 and 8, position alignment portions MSE_A in a quantity corresponding to the number of guides MSS_G may be provided, for example. The mask support MSS may rotate until the guides MSS_G are disposed to contact the respective position alignment portions MSE_A of the mask electrostatic-chuck MSE. When the guides MSS_G are disposed to overlap the position alignment portions MSE_A, the mask support MSS may stop the rotation and be seated on the mask electrostatic-chuck MSE (or the position alignment portion MSE_A). In an embodiment, when the guides MSS_G are disposed not to overlap the position alignment portions MSE_A, the mask support MSS may not be correctly seated on the mask electrostatic-chuck MSE, for example.

The fabrication apparatus DM in an embodiment may include the position alignment portion MSE_A, thereby allowing the mask support MSS to be placed on the mask electrostatic-chuck MSE without being bonded to the mask electrostatic-chuck MSE and the mask MS by welding or the like. Furthermore, the mask support MSS may be automatically replaceable.

In the case of an apparatus that does not include a position alignment portion MSE_A, a structure for supporting the mask MS is fixed to the mask electrostatic-chuck by welding or the like. Accordingly, the structure for supporting the mask MS is manually replaced with another, thereby leading in an increase in process time. In contrast, the fabrication apparatus DM in an embodiment may include the position alignment portion MSE_A and the guide MSS_G, thus allowing the mask support MSS to avoid being bonded to the mask electrostatic-chuck MSE by welding or the like, and enabling the mask support MSS to be automatically replaced by components, such as the transfer component TP.

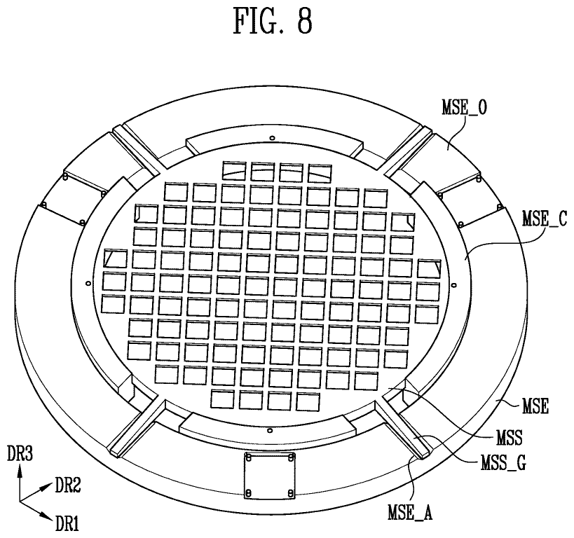

FIGS. 9 to 12 illustrate an embodiment of an apparatus DM′ for fabricating a display device.

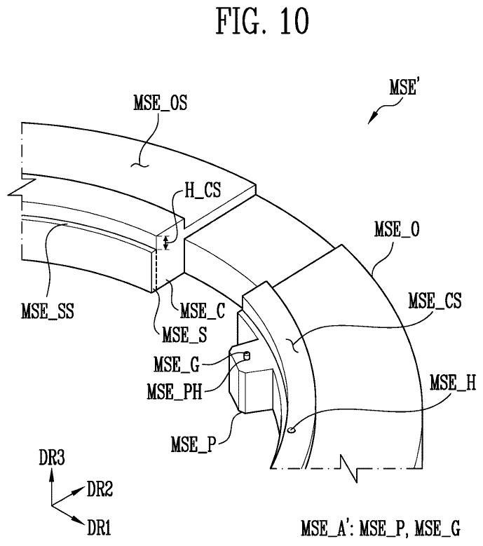

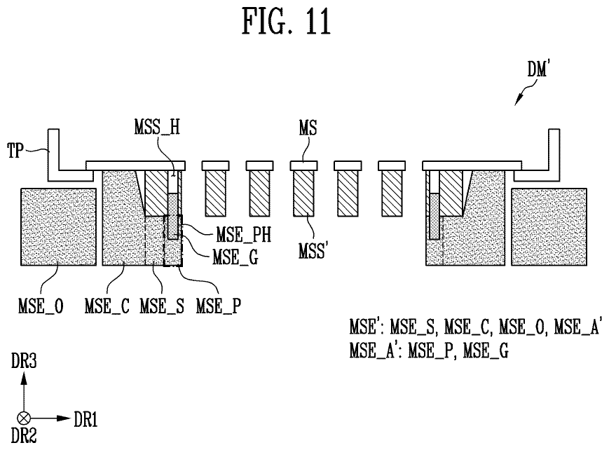

FIG. 9 is a schematic plan view illustrating a mask support MSS′. FIG. 10 is a schematic enlarged view illustrating a mask electrostatic-chuck MSE′. FIG. 11 is a schematic cross-sectional view illustrating the fabrication apparatus DM′. FIG. 12 is a schematic perspective view illustrating the mask support MSS′ placed on the mask electrostatic-chuck MSE′.

Unlike the embodiments illustrated in FIGS. 3 to 8, the embodiments illustrated in FIGS. 9 to 12 may include a position alignment portion MSE_A′ with a different structure and a guide hole MSS_H may be defined. Hereinafter, descriptions of content that overlap the aforementioned details will be omitted, and the following descriptions will focus on differences.

Referring to FIG. 9, the mask support MSS′ in an embodiment may define the guide hole MSS_H therein. The guide hole MSS_H may be formed through a support frame MSS_FR of the mask support MSS′. The guide hole MSS_H may be disposed next (adjacent) to an edge of the support frame MSS_FR.

The guide hole MSS_H may correspond to an opening different from the support openings MSS_OPN. In an embodiment, although both the support openings MSS_OPN and the guide hole MSS_H are openings defined through the support frame MSS_FR, the support openings MSS_OPN and the guide hole MSS_H differ in that deposition material may pass through the support openings MSS_OPN but may not pass through the guide hole MSS_H, for example.

The guide hole MSS_H may have various shapes, in a plan view. In an embodiment, the guide hole MSS_H may have a shape of at least one of a circle, an ellipse, or a polygon in a plan view, for example.

In an embodiment, the guide hole MSS_H may be provided as a plurality of holes. In an embodiment, the guide holes MSS_H may include a first guide hole MSS_H1 and a second guide hole MSS_H2, for example. The first guide hole MSS_H1 and the second guide hole MSS_H2 may be spaced apart from each other and disposed next (adjacent) to an edge of the support frame MSS_FR. Distances between the first guide hole MSS_H1 and the support frame MSS_FR and between the second guide hole MSS_H2 and the support frame MSS_FR may be identical or different. In an embodiment, the first guide hole MSS_H1 and the second guide hole MSS_H2 may be disposed on an identical circumference, or may be disposed on different circumferences, for example.

The first guide hole MSS_H1 and the second guide hole MSS_H2 may have an identical shape as each other. In an embodiment, the first guide hole MSS_H1 and the second guide hole MSS_H2 may have an identical shape and an identical surface area in a plan view, for example. In an embodiment, the first guide hole MSS_H1 and the second guide hole MSS_H2 may have different shapes from each other. In an embodiment, the size of the second guide hole MSS_H2 may be greater than that of the first guide hole MSS_H1, for example. The first guide hole MSS_H1 and the second guide hole MSS_H2 may have different surface areas in a plan view.

Although FIG. 9 illustrates an embodiment in which two guide holes MSS_H are provided, the disclosure is not limited thereto. In an embodiment, the guide hole MSS_H may be provided as a single hole or as three or more holes, for example. In an embodiment, in the case where the guide hole MSS_H is provided as multiple holes, the mask support MSS′ may be more stably seated on the mask electrostatic-chuck MSE′.

Referring to FIG. 10, the position alignment portion MSE_A′ may include a protrusion MSE_P and a pin MSE_G.

The protrusion MSE_P may be connected to the seating portion MSE_S, and may protrude from the seating portion MSE_S. In an embodiment, the protrusion MSE_P may be unitary with the seating portion MSE_S, and may protrude in a direction away from a side surface of the seating portion MSE_S (e.g., in an inward direction), for example.

The protrusion MSE_P may define therein a protrusion hole MSE_PH which passes through at least a portion of the protrusion MSE_P in the third direction DR3. The protrusion hole MSE_PH may completely pass through the protrusion MSE_P, or may pass through only a portion of the protrusion MSE_P.

The pin MSE_G may be inserted into the protrusion hole MSE_PH. In an embodiment, the pin MSE_G may be inserted into the protrusion hole MSE_PH and fixed to the protrusion MSE_P by various methods, such as pressure fitting or screw coupling, for example. The pin MSE_G which is inserted into the protrusion hole MSE_PH may protrude from an upper surface of the protrusion MSE_P.

In a cross-sectional view, the pin MSE_G may have a quadrangular shape, e.g., rectangular shape with a constant width, or may have a trapezoidal shape with a width increasing from one end to an opposite end. In an embodiment, in a cross-sectional view, the pin MSE_G may have a shape with a constant width in the third direction DR3 or may have a trapezoidal shape (or a tapered shape) which increases in width in a direction opposite to the third direction DR3, for example.

Referring to FIGS. 11 and 12, a portion of the pin MSE_G that protrudes from the upper surface of the protrusion MSE_P may be inserted into the guide hole MSS_H. To achieve the aforementioned purpose, a width of the guide hole MSS_H may be equal to that of the pin MSE_G. In an embodiment, the width of the guide hole MSS_H may be greater than that of the pin MSE_G within a range in which the mask support MSS′ is not excessively rotated (or moved) after the pin MSE_G is inserted into the guide hole MSS_H.

In an embodiment, the first guide hole MSS_H1 and the pin MSE_G may have an identical shape and an identical surface area in a plan view. In an embodiment, the second guide hole MSS_H2 may have a shape identical to that of the pin MSE_G in a plan view, and may have a surface area greater than that of the pin MSE_G. However, the disclosure is not limited to the aforementioned embodiment. In an embodiment, in the case where the guide hole MSS_H has a shape identical to that of the pin MSE_G and has a surface area greater than that of the pin MSE_G, the pin MSE_G may be more easily inserted into the guide hole MSS_H.

The guide hole MSS_H may guide the mask support MSS′ to be disposed at a correct position on the mask electrostatic-chuck MSE′. In an embodiment, guide holes MSS_H may be provided in a quantity corresponding to the number of pins MES_G of the position alignment portion MSE_A′, for example. The mask support MSS′ may rotate until the pin MSE_G is disposed at a position at which the pin MSE_G may be inserted into the guide hole MSS_H. When the pin MSE_G is disposed to correspond to the guide hole MSS_H, the mask support MSS′ may stop the rotation to allow the pin MSE_G to be inserted into the guide hole MSS_H.

The fabrication apparatus DM′ in an embodiment may include the position alignment portion MSE_A′, thereby allowing the mask support MSS′ to be placed on the mask electrostatic-chuck MSE′ without being bonded to the mask electrostatic-chuck MSE′ and the mask MS′ by welding or the like. Furthermore, the mask support MSS′ may be automatically replaceable.

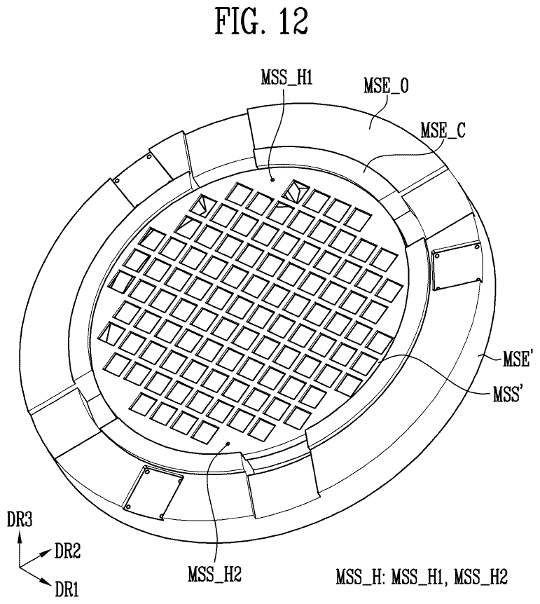

FIG. 13 illustrates an embodiment of an apparatus DM″ for fabricating a display device.

FIG. 13 is a schematic cross-sectional view illustrating the fabrication apparatus DM″.

Unlike the embodiments illustrated in FIGS. 3 to 8, the embodiment illustrated in FIG. 13 may include a substrate electrostatic-chuck moving component S_MP capable of moving the substrate electrostatic-chuck ESC. Hereinafter, descriptions of content that overlap the aforementioned details will be omitted, and the following descriptions will focus on differences.

The substrate electrostatic-chuck moving component S_MP may be disposed next (adjacent) to the substrate electrostatic-chuck ESC. In an embodiment, the substrate electrostatic-chuck moving component S_MP may be disposed above or under the substrate electrostatic-chuck ESC, for example.

The substrate electrostatic-chuck moving component S_MP may move the substrate electrostatic-chuck ESC. In an embodiment, the substrate electrostatic-chuck moving component S_MP may move the substrate electrostatic-chuck ESC in the up-down direction (e.g., the third direction DR3), for example. However, the disclosure is not limited to the above-mentioned example. In an embodiment, the substrate electrostatic-chuck moving component S_MP may move the substrate electrostatic-chuck ESC in the left-right direction (e.g., in the first and second directions DR1 and DR2).

The substrate electrostatic-chuck moving component S_MP may move the substrate electrostatic-chuck ESC to change the shape of the substrate electrostatic-chuck ESC. In an embodiment, the substrate electrostatic-chuck moving component S_MP may move the substrate electrostatic-chuck ESC to change the shape of the substrate electrostatic-chuck ESC such that an upper surface of the substrate electrostatic-chuck ESC bends, for example. The substrate electrostatic-chuck moving component S_MP may move the substrate electrostatic-chuck ESC to change the shape of the substrate SUB that is secured to the substrate electrostatic-chuck ESC. In an embodiment, the substrate electrostatic-chuck moving component S_MP may move the substrate electrostatic-chuck ESC while simultaneously moving the substrate SUB, thereby changing the shape of the substrate SUB such that an upper surface of the substrate SUB bends, for example.

In an embodiment, a plurality of substrate electrostatic-chuck moving components S_MP may be provided. At least some of the substrate electrostatic-chuck moving components S_MP may move the substrate electrostatic-chuck ESC in different directions for respective areas compared to the remaining ones, thereby changing the shape of the substrate electrostatic-chuck ESC. However, the disclosure is not limited to the aforementioned embodiment. In an embodiment, the substrate electrostatic-chuck moving component S_MP may be provided as a single unit and configured such that the substrate electrostatic-chuck ESC moves in different directions for respective areas.

In an embodiment, the substrate electrostatic-chuck moving component S_MP may include a piezo actuator, but the disclosure is not limited thereto. In an embodiment, the substrate electrostatic-chuck moving component S_MP may include various configurations capable of moving the substrate electrostatic-chuck ESC, for example.

The embodiment illustrated in FIG. 13 may not include the aforementioned mask support MSS. Accordingly, the mask MS may bend. The embodiment illustrated in FIG. 13 may include the substrate electrostatic-chuck moving component S_MP, thereby being capable of changing the shape of the substrate SUB such that the substrate SUB bends to correspond to the degree with which the mask MS is bent. In an embodiment, the substrate SUB may bend such that a cross-sectional shape of a lower surface of the substrate SUB is substantially identical to a cross-sectional shape of an upper surface of the mask MS, for example. In accordance with the embodiment illustrated in FIG. 13, the substrate SUB may bend to correspond to the shape of the mask MS so that a gap between the mask MS and the substrate SUB may be minimized, and the parallelism between the upper surface of the mask MS and the lower surface of the substrate SUB may be enhanced.

The embodiment illustrated in FIG. 13 may further include a pressure sensor. The pressure sensor may be disposed next (adjacent) to the substrate electrostatic-chuck ESC. In an embodiment, the pressure sensor may be placed on the upper or lower surface of the substrate electrostatic-chuck ESC, for example. The pressure sensor may measure a pressure applied to the substrate electrostatic-chuck ESC. In an embodiment, the pressure sensor may be provided as a single unit or a plurality of units.

The embodiment illustrated in FIG. 13 may further include a distance sensor. The distance sensor may be disposed next (adjacent) to the mask MS. In an embodiment, the distance sensor may be disposed between the mask MS and the substrate SUB, for example. The distance sensor may measure a distance between the substrate SUB and the mask MS. In an embodiment, the distance sensor may be provided as a single unit or a plurality of units.

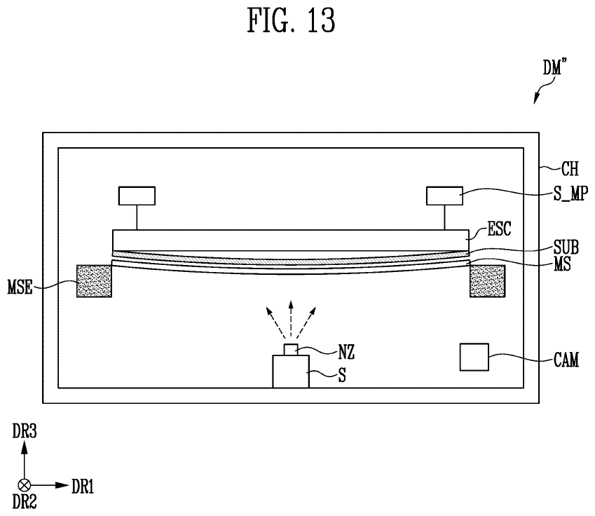

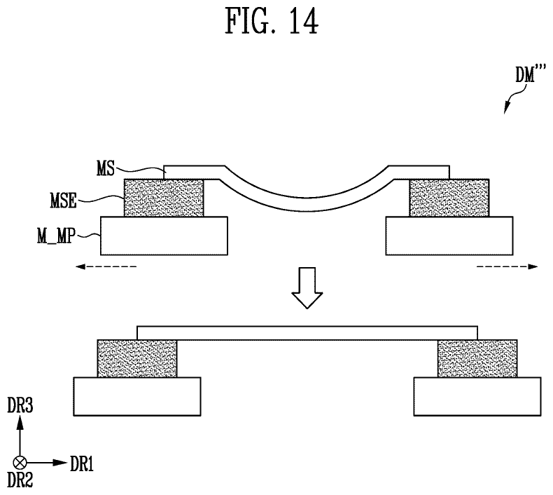

FIGS. 14 and 15 illustrate an apparatus DM″′ for fabricating a display device in an embodiment (e.g., a fourth embodiment).

FIG. 14 is a schematic cross-sectional view illustrating an embodiment of the fabrication apparatus DM′″. FIG. 15 is a schematic plan view illustrating an embodiment of the mask electrostatic-chuck MSE.

Unlike the embodiments illustrated in FIGS. 3 to 8, the embodiment illustrated in FIGS. 14 and 15 may include a mask electrostatic-chuck moving component M_MP capable of moving the mask electrostatic-chuck MSE. Hereinafter, descriptions of content that overlap the aforementioned details will be omitted, and the following descriptions will focus on differences.

Referring to FIG. 14, the mask electrostatic-chuck moving component M_MP may move the mask electrostatic-chuck MSE. In an embodiment, the mask electrostatic-chuck moving component M_MP may move the mask electrostatic-chuck MSE in the left-right direction (e.g., the first and second directions DR1 and DR2), for example.

Referring to FIG. 15, the mask electrostatic-chuck MSE may be provided as plurality of units. In an embodiment, the mask electrostatic-chuck MSE may include a first mask electrostatic-chuck MSE1, a second mask electrostatic-chuck MSE2, a third mask electrostatic-chuck MSE3, and a fourth mask electrostatic-chuck MSE4, for example. The first mask electrostatic-chuck MSE1, the second mask electrostatic-chuck MSE2, the third mask electrostatic-chuck MSE3, and the fourth mask electrostatic-chuck MSE4 may be arranged along the clockwise direction.

Although FIG. 15 illustrates an embodiment in which four mask electrostatic-chucks MSE are provided, the disclosure is not limited thereto. In an embodiment, the mask electrostatic-chucks MSE may be provided as two or more units, for example.

In an embodiment, mask electrostatic-chuck moving components M_MP in a quantity corresponding to the number of mask electrostatic-chucks MSE may be provided. Each of the mask electrostatic-chuck moving components M_MP may be disposed above or below the corresponding mask electrostatic-chuck MSE to move the mask electrostatic-chuck MSE.

The mask electrostatic-chuck moving components M_MP may move the respective mask electrostatic-chucks MSE to change distances between the first mask electrostatic-chuck MSE1, the second mask electrostatic-chuck MSE2, the third mask electrostatic-chuck MSE3, and the fourth mask electrostatic-chuck MSE4. In an embodiment, the mask electrostatic-chuck moving components M_MP may move the respective mask electrostatic-chucks MSE such that each of the first mask electrostatic-chuck MSE1, the second mask electrostatic-chuck MSE2, the third mask electrostatic-chuck MSE3, and the fourth mask electrostatic-chuck MSE4 moves away from or closer to the center of the mask MS, for example. In an embodiment, the mask electrostatic-chuck moving components M_MP may move the respective mask electrostatic-chucks MSE such that the first mask electrostatic-chuck MSE1, the second mask electrostatic-chuck MSE2, the third mask electrostatic-chuck MSE3, and the fourth mask electrostatic-chuck MSE4 are farther apart from each other or closer to each other, for example.

The mask electrostatic-chuck moving component M_MP may move the mask electrostatic-chuck MSE to change the shape of the mask MS. In an embodiment, the mask electrostatic-chuck moving components M_MP may move the mask electrostatic-chucks MSE to tension the mask MS, for example. In the case where each of the first mask electrostatic-chuck MSE1, the second mask electrostatic-chuck MSE2, the third mask electrostatic-chuck MSE3, and the fourth mask electrostatic-chuck MSE4 moves away from the center of the mask MS, the mask MS may be tensioned. The mask electrostatic-chuck moving components M_MP may move the mask electrostatic-chucks MSE to change the shape of the mask MS such that the mask MS bends. In the case where each of the first mask electrostatic-chuck MSE1, the second mask electrostatic-chuck MSE2, the third mask electrostatic-chuck MSE3, and the fourth mask electrostatic-chuck MSE4 moves toward the center of the mask MS, the mask MS may bend.

The embodiment illustrated in FIGS. 14 and 15 may not include the aforementioned mask support MSS, but may include the mask electrostatic-chuck moving component M_MP which moves the mask electrostatic-chuck MSE. Accordingly, the mask MS may be tensioned so that the upper surface of the mask MS may be leveled. As a result, the gap between the mask MS and the substrate SUB may be minimized, and the parallelism between the upper surface of the mask MS and the lower surface of the substrate SUB may be enhanced.

Hereinbelow, a display device DD in an embodiment will be described with reference to FIGS. 16 to 18.

FIG. 16 is a plan view illustrating an embodiment of the display device DD. The display device DD in FIG. 16 may be a display device DD fabricated using the fabrication apparatus DM, DM′, DM″, or DM″′ described above.

Referring to FIG. 16, the display device DD (a display panel) may include a display area DA and a non-display area NDA. The display device DD may display an image through the display area DA. The non-display area NDA may be formed around the display area DA.

The display device DD may include a base layer BSL, sub-pixels SP, and/or pads PD.

The sub-pixels SP may be arranged in the display area DA on the base layer BSL. The sub-pixels SP may be arranged in a matrix form in a first direction DR1 and a second direction DR2 crossing the first direction DR1. However, the disclosure is not limited to the aforementioned embodiment. In an embodiment, the sub-pixels SP may be arranged in a zigzag pattern in the first direction DR1 and the second direction DR2, for example. In an embodiment, the sub-pixels SP may be arranged in a pentile form, for example. The first direction DR1 may refer to a row direction, and the second direction DR2 may refer to a column direction. Two or more sub-pixels among the sub-pixels SP may form a single pixel PXL.

Components for controlling the sub-pixels SP may be disposed in the non-display area NDA on the base layer BSL. In an embodiment, wirings connected to the sub-pixels SP, such as gate lines and data lines, may be disposed in the non-display area NDA, for example.

The pads PD may be arranged in the non-display area NDA on the base layer BSL. The pads PD may be electrically connected to the sub-pixels SP through the wirings. In an embodiment, the pads PD may be connected to the sub-pixels SP through the data lines, for example.

Voltages and signals desired for the operation of the components included in the display device DD may be provided from a driver integrated circuit through the pads PD. In an embodiment, the data lines may be connected to the driver integrated circuit through the pads PD, for example. In an embodiment, power voltages may be received from the driver integrated circuit through the pads PD, for example.

In an embodiment, a circuit board may be electrically connected to the pads PD by a conductive adhesive component such as an anisotropic conductive film. The circuit board may be a flexible circuit board or flexible film which includes or consists of flexible material. The driver integrated circuit may be disposed (e.g., mounted) on the circuit board and be electrically connected to the pads PD.

In an embodiment, the display area DA may have various shapes. The display area DA may have a closed-loop shape, including linear and/or curved sides. In an embodiment, the display area DA may have shapes, such as a polygon, a circle, a semicircle, and an ellipse, for example.

In an embodiment, the display device DD may include a planar display surface. In an embodiment, the display device DD may include a display surface which is at least partially rounded. In an embodiment, the display device DD may be bendable, foldable, or rollable. In the aforementioned cases, the display device DD and/or the base layer BSL may include materials having flexible properties.

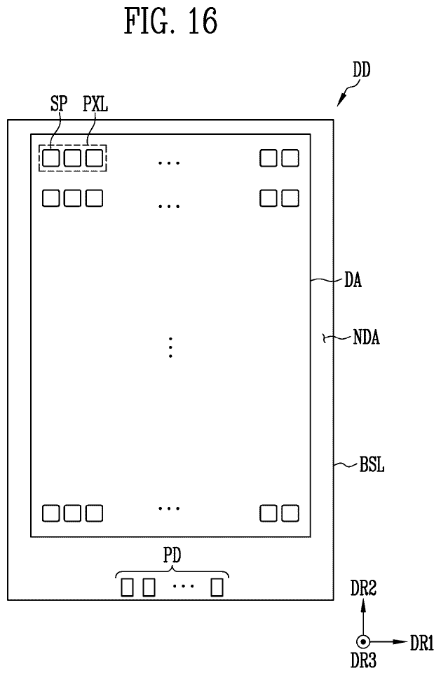

FIG. 17 is a plan view illustrating an embodiment of a sub-pixel.

Referring to FIG. 17, the pixel PXL may include first to third sub-pixels SP1 to SP3 arranged in the first direction DR1.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

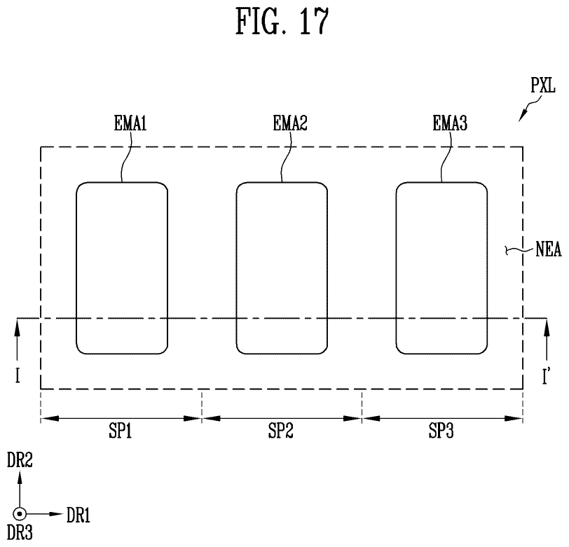

The first emission area EMA1 may be an area where light is emitted from a first emission layer EML1 (refer to FIG. 18) of the first sub-pixel SP1. The second emission area EMA2 may be an area where light is emitted from a second emission layer EML2 (refer to FIG. 18) of the second sub-pixel SP2. The third emission area EMA3 may be an area where light is emitted from a third emission layer EML3 (refer to FIG. 18) of the third sub-pixel SP3.

FIG. 18 is a cross-sectional view taken along line I-I′ of FIG. 17.

Referring to FIG. 18, the first to third sub-pixels SP1 to SP3 may respectively include the emission areas EMA1, EMA2, and EMA3. The non-emission area NEA may be disposed between the emission areas EMA1, EMA2, and EMA3 of the first to third sub-pixels SP1 to SP3.

Each of the first to third sub-pixels SP1 to SP3 may include a pixel circuit layer PCL, a display element layer DPL, and/or a thin-film encapsulation layer TFE which are sequentially stacked on the base layer BSL.

The base layer BSL may form a foundational surface. The base layer BSL may include transparent insulating material to allow light transmission. The base layer BSL may be a rigid substrate or a flexible substrate. In an embodiment, the rigid substrate may be one of a glass substrate, a quartz substrate, a glass ceramic substrate, or a crystalline glass substrate, for example. The flexible substrate may be either a film substrate or a plastic substrate which includes polymer organic material. In an embodiment, the flexible substrate SUB may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate, for example, but the disclosure is not limited thereto. In an embodiment, the base layer BSL may be a substrate including silicon, for example. In an embodiment, the display device DD may be an organic light-emitting diode (“OLED”) on silicon (“OLEDoS”) display device which includes a display panel formed on a silicon substrate.

The pixel circuit layer PCL may include a buffer layer BFL, a gate insulating layer GI, an inter-insulating layer ILD, a passivation layer PSV, and/or a via layer VIA which are sequentially stacked on the base layer BSL in the third direction DR3.

The buffer layer BFL may be an inorganic insulating layer including inorganic material. The buffer layer BFL may include at least one of silicon nitride (SiNₓ), silicon oxide (SiOₓ), silicon oxynitride (SiOₓN_{y}), or metal oxide, such as aluminum oxide (AlOₓ). The buffer layer BFL may be provided as a single layer, or as a multilayer structure with at least two or more layers. In case that the buffer layer BFL is provided as a multilayer structure, the respective layers may include or consist of an identical material or different materials from each other. The buffer layer BFL may be omitted depending on the material of the base layer BSL, processing conditions, or the like.

A transistor T may be placed on the buffer layer BFL. The transistor T may include an active pattern ACT, a gate electrode GE, a first transistor electrode TE1, and/or a second transistor electrode TE2.

The active pattern ACT may be placed on the buffer layer BFL. The active pattern ACT may include a polysilicon semiconductor. In an embodiment, the active pattern ACT may be formed through a low-temperature polysilicon process, for example. However, the disclosure is not limited to the aforementioned embodiment, and the active pattern ACT may include or consist of an oxide semiconductor, a metal oxide semiconductor, or the like.

The active pattern ACT may include a channel area, a first contact area extended to a first end of the channel area, and a second contact area extended to a second end of the channel area. The channel area, the first contact area, and the second contact area may each include an undoped semiconductor layer or a semiconductor layer doped with an impurity. In an embodiment, each of the first contact area and the second contact area may include a semiconductor layer doped with an impurity, and the channel area may include an undoped semiconductor layer, for example. In an embodiment, an n-type impurity may be used as the impurity, for example, but the disclosure is not limited thereto. One of the first contact area or the second contact area may be a source area, and a remaining (the other) one may be a drain area.

The gate insulating layer GI may be placed on the active pattern ACT. The gate insulating layer GI may include an inorganic layer (or an inorganic insulating layer) including inorganic material. In an embodiment, the gate insulating layer GI may include at least one of silicon nitride (SiNₓ), silicon oxide (SiOₓ), silicon oxynitride (SiOₓN_{y}), or metal oxide, such as aluminum oxide (AlOₓ), for example. However, the material of the gate insulating layer GI is not limited to the foregoing embodiments. In an embodiment, the gate insulating layer GI may include an organic layer (an organic insulating layer) including organic material. The gate insulating layer GI may be provided as a single layer, or as a multilayer structure with at least two or more layers. The gate electrode GE may be placed on the gate insulating layer GI. The gate electrode GE may be placed over the channel area of the active pattern ACT. The gate electrode GE may have a single-layer structure including or consisting of one or combination selected from the group including or consisting of copper (Cu), molybdenum (Mo), tungsten (W), aluminum neodymium (AlNd), titanium (Ti), aluminum (Al), silver (Ag), and any alloys thereof, or may have a double-layer or multi-layer structure including molybdenum (Mo), titanium (Ti), copper (Cu), aluminum (Al), or silver (Ag) to reduce wiring resistance.

An inter-dielectric ILD may be placed on the gate electrode GE. The inter-dielectric ILD and the gate insulating layer GI may include an identical material. The inter-dielectric ILD may include one or more materials selected from among materials exemplified as the constituent material of the gate insulating layer GI.

The first transistor electrode TE1 and the second transistor electrode TE2 may be placed on the inter-dielectric ILD. The first transistor electrode TE1 of the transistor T may extend to the first contact area of the active pattern ACT through a contact hole which passes through the inter-dielectric ILD and the gate insulating layers GI. In the case where the first contact area is a source area, the first transistor electrode TE1 may be a first source electrode.

The second transistor electrode TE2 of the transistor T may extend to the second contact area of the second end of the active pattern ACT through a contact hole which passes through the inter-dielectric ILD and the gate insulating layers GI. In the case where the second contact area is a drain area, the second transistor electrode TE2 may be a second drain electrode.

Each of the first transistor electrode TE1 and the second transistor electrode TE2 may include the same material as that of the gate electrode GE, or include one or more materials selected from among materials exemplified as the constituent materials of the gate electrode GE.

The passivation layer PSV may be placed on the first transistor electrode TE1 and the second transistor electrode TE2. The passivation layer PSV (e.g., a protective layer) may include or consist of an inorganic layer (or an inorganic insulating layer) including inorganic material, or an organic layer (or an organic insulating layer) including organic material. The inorganic layer may include, e.g., at least one of silicon oxide (SiOₓ), silicon nitride (SiNₓ), silicon oxynitride (SiOₓN_{y}), or metal oxide, such as aluminum oxide (AlOₓ). The organic layer may include, e.g., at least one of polyacrylates resin, epoxy resin, phenolic resin, polyamides resin, polyimides rein, unsaturated polyesters resin, polyphenylen ethers resin, polyphenylene sulfides resin, or benzocyclobutene resin.

In an embodiment, the passivation layer PSV and the inter-insulating layer ILD may have an identical material, but the disclosure is not limited thereto. The passivation layer PSV may be provided as a single layer, or as a multilayer structure with at least two or more layers.

The via layer VIA may be placed on the passivation layer PSV. The via layer VIA and the passivation layer PSV may include an identical material. The via layer VIA may include one or more materials selected from among the materials exemplified as the constituent materials of the passivation layer PSV. In an embodiment, the via layer VIA may include an organic layer including or consisting of organic material.

The display element layer DPL may be placed on the pixel circuit layer PCL. The display element layer DPL may include a light-emitting element LD configured to emit light. The first to third sub-pixels SP1 to SP3 may respectively include first to third light-emitting elements LD1 to LD3.

The first light-emitting element LD1 may include an anode electrode AE, a first emission layer EML1, and a cathode electrode CE. The second light-emitting element LD2 may include an anode electrode AE, a second emission layer EML2, and a cathode electrode CE. The third light-emitting element LD3 may include an anode electrode AE, a third emission layer EML3, and a cathode electrode CE. In an embodiment, each of the first to third light-emitting elements LD1 to LD3 may be a top-emission type organic light-emitting element, for example.

The respective anode electrodes AE of the first, second, and third sub-pixels SP1, SP2, and SP3 may be disposed in the corresponding emission areas EMA1, EMA2, and EMA3, and may be spaced apart from each other. The anode electrode AE of each of the sub-pixels SP may be electrically connected to the first transistor electrode TE1 of the transistor T of the corresponding sub-pixel SP through a corresponding contact hole which passes through the via layer VIA and the passivation layer PSV.

A bank PDL may be placed on the anode electrode AE. The bank PDL may define (or partition) the respective emission areas EMA1, EMA2, and EMA3 of the sub-pixels SP. The bank PDL may define openings which partially expose the respective anode electrodes AE of the sub-pixels SP.

The bank PDL may include an organic insulating layer including or consisting of organic material. The organic material may include acryl resin, epoxy resin, phenolic resin, polyamide resin, polyimide resin, or the like. The disclosure is not limited to the aforementioned embodiment, and the bank PDL may include an inorganic insulating layer including or consisting of inorganic material.

In an embodiment, the bank PDL may include light-absorbing material or be coated with light absorbent, thus functioning to absorb light introduced from the outside. In an embodiment, the bank PDL may include carbon-based black pigment, for example. The disclosure is not limited to the aforementioned embodiment. The bank PDL may include opaque metal, such as chrome (Cr), molybdenum (Mo), an alloy (MoTi) of molybdenum (Mo) and titanium (Ti), tungsten (W), vanadium (V), niobium (Nb), tantalum (Ta), manganese (Mn), cobalt (Co), or nickel (Ni), having relatively high light absorptivity.

The emission layer EML of each of the sub-pixels SP may be placed on the corresponding anode electrode AE exposed from the bank PDL. The cathode electrode CE may be placed on the emission layer EML. The cathode electrode CE may extend across all of the first to third sub-pixels SP1 to SP3. In an embodiment, the cathode electrode CE may be provided as a common electrode, for example, but the disclosure is not limited thereto.

The cathode electrode CE may include or consist of a metal layer including or consisting of material, such as silver (Ag), magnesium (Mg), aluminum (Al), platinum (Pt), palladium (Pd), gold (Au), nickel (Ni), neodymium (Nd), iridium (Ir), chrome (Cr), or any alloys thereof, and/or a transparent conductive layer including or consisting of material, such as indium tin oxide (“ITO”), indium zinc oxide (“IZO”), zinc oxide (ZnO), or indium tin zinc oxide (“ITZO”). In an embodiment, the cathode electrode CE may include a multilayer structure with two or more layers including a thin metal layer. In an embodiment, the cathode electrode CE may include a triple-layer structure of ITO/Ag/ITO, for example.

The thin-film encapsulation layer TFE may be placed on the display element layer DPL. The thin-film encapsulation layer TFE may have a single-layer or multilayer structure. The thin-film encapsulation layer TFE may include an insulating layer which covers the light-emitting element LD. The thin-film encapsulation layer TFE may include at least one inorganic layer and at least one organic layer. In an embodiment, the thin-film encapsulation layer TFE may have a structure formed by alternately stacking the inorganic layers and the organic layers, for example. In an embodiment, the thin-film encapsulation layer TFE may include a first inorganic layer, an organic layer placed on the first inorganic layer, and a second inorganic layer placed on the organic layer, for example.

A sensing layer TS may be placed on the thin-film encapsulation layer TFE. The sensing layer TS may include a first insulating layer INS1, a first conductive layer MT1, a second insulating layer INS2, a second conductive layer MT2, and a third insulating layer INS3.

The first insulating layer INS1 may be placed on the thin-film encapsulation layer TFE. The first insulating layer INS1 may include an inorganic insulating layer including inorganic material. The inorganic insulating layer may include inorganic insulating material, such as silicon oxide (SiOₓ), silicon nitride (SiNₓ), silicon oxynitride (SiOₓN_{y}), aluminum oxide (AlₓO_{y}), titanium oxide (TiOₓ), tantalum oxide (TaₓO_{y}), hafnium oxide (HfOₓ), or zinc oxide (ZnOₓ). In an embodiment, the first insulating layer INS1 may be omitted, or may be configured as an uppermost layer of the thin-film encapsulation layer TFE.

The first conductive layer MT1 may be placed on the first insulating layer INS1. The first conductive layer MT1 may be partially open to prevent overlap with the respective light-emitting elements LD of the sub-pixels SP. In an embodiment, the first conductive layer MT1 may be placed over the non-emission area NEA around the emission areas EMA1, EMA2, and EMA3, for example.

The first conductive layer MT1 may include a metal layer or a transparent conductive layer. In an embodiment, the metal layer may include molybdenum, titanium, copper, aluminum, or any alloys thereof, for example. The transparent conductive layer may include at least one of ITO, IZO, zinc oxide (ZnO), ITZO, poly(3,4-ethylenedioxythiophene) (“PEDOT”), or metal nanowires, but is not limited thereto. The first conductive layer MT1 may form a connection electrode which connects sensing electrodes.

The second insulating layer INS2 may be placed on the first conductive layer MT1. The second insulating layer INS2 and the first insulating layer INS1 may include an identical material. The second insulating layer INS2 may include one or more materials selected from among materials exemplified as the constituent materials of the first insulating layer INS1.

The second conductive layer MT2 may be placed on the second insulating layer INS2. The second conductive layer MT2 may be partially open to prevent overlap with the respective light-emitting elements LD of the sub-pixels SP. In an embodiment, the second conductive layer MT2 may be placed over the non-emission area NEA around the emission areas EMA1, EMA2, and EMA3, for example.

The second conductive layer MT2 and the first conductive layer MT1 may include an identical material. The second conductive layer MT2 may include one or more materials selected from among materials exemplified as the constituent materials of the first conductive layer MT1.

The second conductive layer MT2 may be electrically connected to the first conductive layer MT1 through a contact hole which passes through the second insulating layer INS2. The second conductive layer MT2 may form sensing electrodes.

The third insulating layer INS3 may be placed on the second conductive layer MT2. The third insulating layer INS3 may include an organic insulating layer including organic material. However, the disclosure is not limited to the aforementioned embodiment. In an embodiment, the third insulating layer INS3 may include an inorganic layer, or may have a structure in which organic layers and inorganic layers are alternately stacked.

A light-blocking layer LBP may be placed on the display element layer DPL, the thin-film encapsulation layer TFE, and/or the sensing layer TS. The light-blocking layer LBP may define therein an opening which is formed over the light-emitting element LD. In an embodiment, the light-blocking layer LBP may be placed over the non-emission area NEA around the emission areas EMA1, EMA2, and EMA3, for example.

The light-blocking layer LBP may include light-blocking material to prevent light leakage and color mixing defects. In an embodiment, the light-blocking layer LBP may include a black matrix, for example, but is not limited thereto. In an embodiment, the light-blocking layer LBP may include carbon black (“CB”) and/or titan black (“TiBK”).

A color filter layer CFL may be placed on the light-blocking layer LBP. The color filter layer CFL may include color filters CF1 to CF3 corresponding to the respective colors of the sub-pixels SP. Since the color filters CF1 to CF3 corresponding to the respective colors of the first to third sub-pixels SP1 to SP3 are arranged, a full-color image may be displayed.

The color filter layer CFL may include a first color filter CF1 provided in the first sub-pixel SP1 to selectively transmit light emitted from the first sub-pixel SP1, a second color filter CF2 provided in the second sub-pixel SP2 to selectively transmit light emitted from the second sub-pixel SP2, and a third color filter CF3 provided in the third sub-pixel SP3 to selectively transmit light emitted from the third sub-pixel SP3.

In an embodiment, the first color filter CF1, the second color filter CF2, and the third color filter CF3 may be respectively a red color filter, a green color filter, and a blue color filter, but the disclosure is not limited thereto.

The first color filter CF1 may include a color filter material that selectively transmits light of first color (or red). In an embodiment, in the case where the first sub-pixel SP1 is a red sub-pixel, the first color filter CF1 may include a red color filter material, for example.

The second color filter CF2 may include a color filter material that selectively transmits light of a second color (or green). In an embodiment, in the case where the second sub-pixel SP2 is a green sub-pixel, the second color filter CF2 may include a green color filter material, for example.

The third color filter CF3 may include a color filter material that selectively transmits light of a third color (or blue). In an embodiment, in the case where the third sub-pixel SP3 is a blue sub-pixel, the third color filter CF3 may include a blue color filter material, for example.

An overcoat layer OC may be provided on the color filter layer CFL. The overcoat layer OC may include various materials suitable for protecting underlying layers from foreign substances, such as dust, water, or the like. In an embodiment, the overcoat layer OC may include at least one of an inorganic insulating layer or an organic insulating layer, for example. In an embodiment, the overcoat layer OC may include epoxy, for example, but the disclosure is not limited thereto.

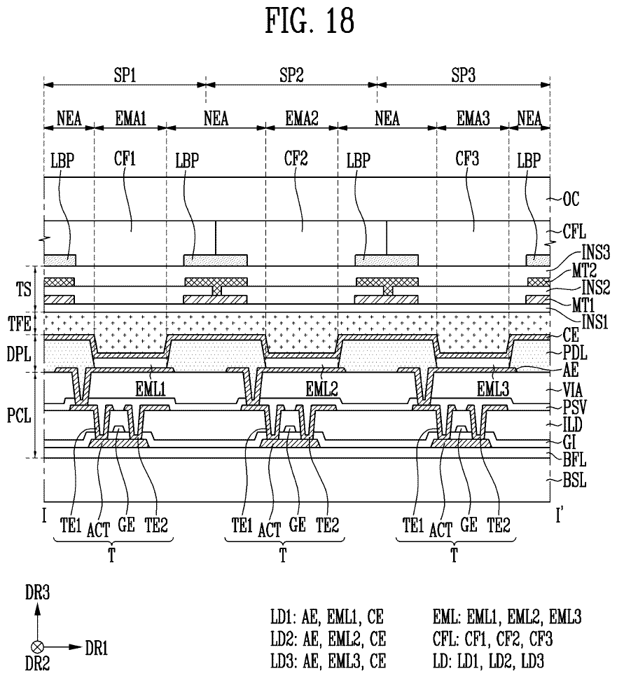

Hereinafter, a method of fabricating a display device DD will be described with reference to FIG. 19.

FIG. 19 is a flowchart illustrating an embodiment of the method of fabricating the display device DD. The method of fabricating the display device DD in accordance with the disclosure may be a method of fabricating the display device DD using the fabrication apparatus DM, DM′, DM″, or DM″′ described above.

Referring to FIG. 19, the method of fabricating the display device DD may include operation S100 of forming the pixel circuit layer PCL on the substrate SUB, operation S200 of forming the light-emitting elements LD on the pixel circuit layer PCL, and operation S300 of forming the thin-film encapsulation layer TFE on the light-emitting elements LD.

Referring to FIG. 19 together with FIG. 18, at operation S100 of forming the pixel circuit layer PCL on the substrate SUB, circuit elements may be patterned on the substrate SUB (which may correspond to the base layer BSL), and the pixel circuit layer PCL may be provided.

In an embodiment, a conductive layer, an insulating layer, or the like on the substrate SUB may be formed based on a general process for fabricating a semiconductor device. In an embodiment, the conductive layer or the insulating layer on the substrate SUB may be formed through a photolithography process, may be etched by various methods (e.g., wet etching, dry etching, or the like) and may be deposited by various methods (e.g., sputtering, chemical vapor deposition, or the like), for example. However, the disclosure is not limited to a predetermined example.

At operation S100 of forming the pixel circuit layer PCL on the substrate SUB, the transistors T may be patterned on the substrate SUB.

At operation S200 of forming the light-emitting elements LD on the pixel circuit layer PCL, the anode electrodes AE, the emission layers EML1 to EML3, and the cathode electrode CE may be provided to form the first to third light-emitting elements LD1 to LD3.

At operation S200 of forming the light-emitting elements LD on the pixel circuit layer PCL, the anode electrodes AE may be patterned, and the bank PDL which overlaps the anode electrodes AE may be patterned.

Thereafter, the step of depositing the first to third emission layers EML1 to EML3 on the anode electrodes AE may be performed. The first to third emission layers EML1 to EML3 may be deposited using the fabrication apparatus DM, DM′, DM″, or DM″′ described above. In an embodiment, materials for forming the first to third emission layers EML1 to EML3 may be applied onto the anode electrodes AE through the mask MS, for example. To achieve the aforementioned purpose, the pattern of the mask MS may correspond to the patterns of the first to third emission layers EML1 to EML3. Subsequently, the cathode electrode CE may be formed on the first to third emission layers MEL1 to EML3.

At operation S300 of forming the thin-film encapsulation layer TFE on the light-emitting elements LD, the thin-film encapsulation layer TFE may be formed on the light-emitting elements LD1 to LD3. The layers provided under the thin-film encapsulation layer TFE may be passivated.

Subsequently, in an embodiment, the sensing layer TS, the light-blocking layer LBP, and the color filter layer CFL may be formed, thus providing the display device DD.

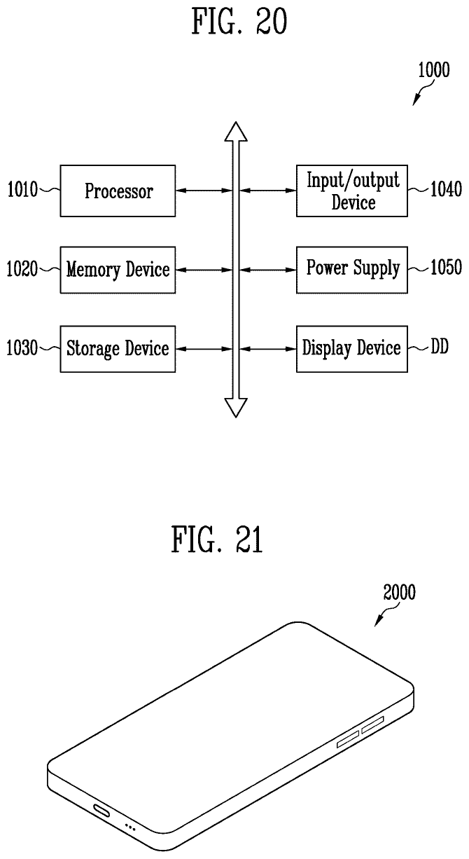

Hereinafter, an electronic device 1000 including the display device DD fabricated according to the aforementioned fabrication method will be described with reference to FIGS. 21 to 23.

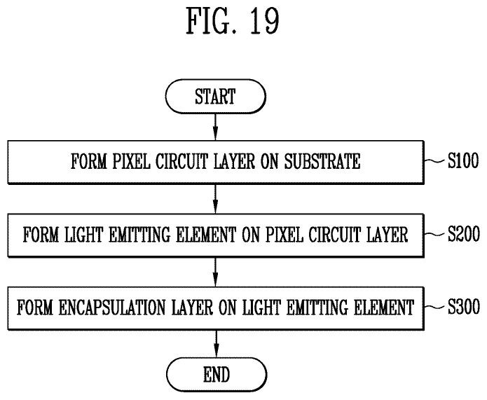

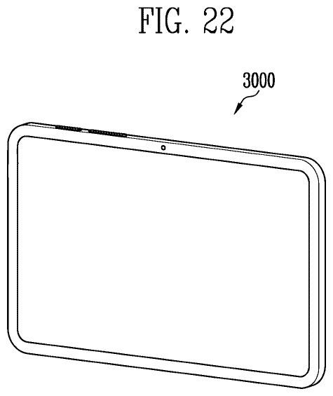

FIG. 20 is a block diagram illustrating an embodiment of an electronic device 1000 including the display device DD of FIG. 18. FIG. 21 is a perspective view illustrating an embodiment of a smartphone 2000 which may be implemented using the electronic device 1000 of FIG. 20. FIG. 22 is a perspective view illustrating an embodiment of a tablet computer 3000 which may be implemented using the electronic device 1000 of FIG. 20.

Referring to FIG. 20, the electronic device 1000 may include a processor 1010, a memory device 1020, a storage device 1030, an input/output (“I/O”) device 1040, a power supply 1050, and a display device DD.

In an embodiment, as illustrated in FIG. 21, the electronic device 1000 may be implemented as a smartphone 2000. In an embodiment, as illustrated in FIG. 22, the electronic device 1000 may be implemented as a tablet computer 3000. However, the aforementioned embodiments are illustrative, and the electronic device 1000 is not limited to the aforementioned embodiments. In an embodiment, the electronic device 1000 may include an electronic device (or a computing system) including the aforementioned display device DD, such as a digital television (“TV”), a three-dimensional (3D) TV, a personal computer (“PC”), a home appliance, a laptop computer, a mobile phone, a video phone, a smart pad, a smartwatch, a head-mounted display device, a personal digital assistant (“PDA”), a potable multimedia player (“PMP”), a digital camera, a music player, a portable game console, or a navigation system, for example.

The processor 1010 may perform various tasks and operations. In an embodiment, the processor 1010 may include an application processor, a graphic processing unit, a microprocessor, a central processing unit (“CPU”), or the like. The processor 1010 may be connected to other components of the electronic device 1000 through a bus system. In an embodiment, the bus system may include a peripheral component interconnect (“PCI”) bus. The processor 1010 may provide the display device DD with a data stream to be displayed on the display device DD.

The memory device 1020 may be provided as a working memory and/or a buffer memory of the electronic device 1000 and/or the processor 1010. In an embodiment, the memory device 1020 may include volatile memory devices, such as a dynamic random access memory (“DRAM”), a static random access memory (“SRAM”), and a mobile DRAM.

The storage device 1030 may store data in response to control from the processor 1010. The storage device 1030 may include a nonvolatile storage medium which retains data even when the power of the electronic device 1000 is turned off. In an embodiment, the storage device 1030 may include a solid state drive (“SSD”), a hard disk drive (“HDD”), or the like.

The I/O device 1040 may include user input devices, such as a keyboard, a keypad, a touchpad, a touch screen, and a mouse, and output devices, such as a speaker and a printer.

The power supply 1050 may supply power desired to perform the operation of the electronic device 1000. In an embodiment, the power supply 1050 may be a power management integrated circuit (“PMIC”), for example. In an embodiment, the power supply 1050 may include a battery, for example.

The display device DD may display an image in response to control from the processor 1010. The display device DD may be connected to other components of the electronic device 1000 through a bus system and/or other communication links. The display device DD may be implemented as the display device DD of FIG. 18. The display device DD may display images on the pixels PXL. In an embodiment, each of the pixels PXL may be configured as illustrated in FIG. 17.

An embodiment of the disclosure may provide an apparatus for fabricating a display device, in which a mask may be appropriately secured to minimize a gap between the mask and a substrate and improve parallelism between the mask and the substrate.

An embodiment of the disclosure may provide an apparatus for fabricating a display device, capable of automatically replacing a mask support which supports the mask with another.

The effects of the disclosure are not limited by the foregoing, and other various effects are anticipated herein.

Although illustrative embodiments and application examples have been described, it should be noted that other embodiments and modifications may be derived from the disclosure provided. Accordingly, the concepts of the disclosure are not limited to the foregoing embodiments, but rather to the broader scope of the presented claims and various obvious modifications and equivalent arrangements.

What is claimed is:

1. An apparatus for fabricating a display device, the apparatus comprising:
a mask electrostatic-chuck;
a mask support placed on the mask electrostatic-chuck; and
a mask placed on the mask support, the mask electrostatic-chuck comprising:
a seating portion onto which the mask support is seated;
a contact portion configured to contact the mask; and
a position alignment portion configured to align a position of the mask support.

2. The apparatus according to claim 1,
wherein the mask electrostatic-chuck further comprises a peripheral portion disposed outside the contact portion, and
wherein a height of the peripheral portion is lower than a height of the contact portion.

3. The apparatus according to claim 2, wherein a height of the seating portion is lower than the height of the contact portion.

4. The apparatus according to claim 2,
wherein the seating portion and the contact portion have different heights from each other, and
wherein a difference between the heights of the seating portion and the contact portion is equal to or greater than a thickness of the mask support.

5. The apparatus according to claim 2, further comprising a transfer component configured to transfer at least one of the mask support or the mask, and
wherein the transfer portion does not contact the peripheral portion.

6. The apparatus according to claim 2, further comprising:
a camera,
wherein the camera correspond to the camera hole, and
wherein the camera captures an image of the mask.

7. The apparatus according to claim 2, wherein the position alignment portion includes a groove defined in the peripheral portion.

8. The apparatus according to claim 7, wherein in a cross-sectional view, the groove has a constant width, or a width decreasing from one end of the groove to an opposite end of the groove.

9. The apparatus according to claim 7,
wherein the mask support comprises:
a support frame; and
a guide which is connected to the support frame and protrudes from the support frame, and
wherein the guide is placed on the position alignment portion.

10. The apparatus according to claim 9, wherein the guide has a rod shape in a plan view.

11. The apparatus according to claim 9,
wherein the mask support further comprises an outer guide frame connected to the guide, and
wherein the outer guide frame has a ring shape in a plan view.

12. The apparatus according to claim 2,
wherein the position alignment portion comprises:
a protrusion which is connected to the seating portion and protrudes from the seating portion; and
a pin,
wherein a protrusion hole passes through at least a portion of the protrusion,
wherein the pin is inserted into the protrusion hole, and
wherein the pin protrudes further than an upper surface of the protrusion.

13. The apparatus according to claim 12,
wherein the contact portion is connected to the seating portion, and
wherein the peripheral portion is connected to the contact portion.

14. The apparatus according to claim 12, wherein in a cross-sectional view, the pin has a constant width, or a width decreasing from one end of the pin to an opposite end of the pin.

15. The apparatus according to claim 12,
wherein a guide hole which passes through the mask support is defined in the mask support, and
wherein the pin is inserted into the guide hole.

16. The apparatus according to claim 15,
wherein the guide hole includes a first guide hole and a second guide hole, and
wherein the second guide hole has a larger area than an area of the first guide hole, in a plan view.

17. An apparatus for fabricating a display device, the apparatus comprising:
a substrate;
a substrate electrostatic-chuck placed on the substrate;
a mask configured to correspond to a pattern of a material formed on the substrate;
a mask electrostatic-chuck disposed under the mask; and
a substrate electrostatic-chuck moving component configured to move the substrate electrostatic-chuck, and
wherein the substrate electrostatic-chuck moving component moves the substrate electrostatic-chuck and changes a shape of the substrate.

18. The apparatus according to claim 17, further comprising:
a pressure sensor configured to measure a pressure applied to the substrate; and
a distance sensor configured to measure a distance between the substrate and the mask,
wherein the substrate is bendable by the substrate electrostatic-chuck moving component.

19. An apparatus for fabricating a display device, the apparatus comprising:
a substrate;
a substrate electrostatic-chuck placed on the substrate;
a mask configured to correspond to a pattern of a material formed on the substrate;
a mask electrostatic-chuck disposed under the mask; and
a mask electrostatic-chuck moving component configured to move the mask electrostatic-chuck, and
wherein the mask electrostatic-chuck moving component moves the mask electrostatic-chuck and changes a shape of the mask.

20. The apparatus according to claim 19,
wherein the mask electrostatic-chuck is provided in plural,
wherein mask electrostatic-chucks are configured to be movable and be spaced apart from each other,
wherein the mask electrostatic-chuck moving component comprises a number of mask electrostatic-chuck moving components corresponding to a number of the mask electrostatic-chucks, and
wherein the mask electrostatic-chuck moving component is configured to tension the mask.
